(19) United States
(12) Patent Application Publication
(10) Pub. No.: US 2008/0089040 A1
(43) Pub. Date: Apr. 17, 2008

(54) LAPTOP POWER RECEPTACLE

(76) Inventors: DAVID C. REED, Tucson, AZ (US); Max D. Smith, Tucson, AZ (US)

Correspondence Address: DILLON & YUDELL, LLP, 8911 N CAPITAL OF TEXAS HWY, SUITE 2110, AUSTIN, TX, 78759, US

(21) Appl. No.: 11/549,695

(22) Filed: Oct. 16, 2006

(51) Int. Cl. H05K 5/00

(52) U.S. Cl. 361/752

(57) ABSTRACT

A method and system for improving the connection for the receptacle used to receive external electrical power and transfer power to the mother board in a laptop computer. The laptop power receptacle is provided a robust connection that is capable of absorbing external forces of the power cable. A power supply is connected to a first female receptacle, which is fastened to the laptop casing. Inside the laptop computer, the first female receptacle is connected to a male receptacle by flexible conductive wire. The male receptacle fits into a second female power receptacle on the mother board. Since the external power supply cable is indirectly attached to the mother board via the flexible wire, the solder joints of the power receptacle on the mother board never receive stress, regardless of how much stress is applied to the external power cable.

### BACKGROUND OF THE INVENTION

1. Technical Field

The present invention generally relates to power receptacles and in particular to power receptacles of electrical devices that are powered via an external power supply.

2. Description of the Related Art

In today's laptop computers (an in many other portable, plug-in electrical devices), external power is transferred to an internal mother board through a power receptacle residing on the mother board. The power receptacle is connected to the laptop's mother board by directly soldering the receptacle onto the mother board. External power is then transferred to the receptacle from the external power supply via a power adapter cable/cord having a first end that plugs into the receptacle and a second end that plugs into the external power supply.

Whenever the power adapter cable is pulled, or jerked, or is caught on an object while the cable is connected to the power receptacle, the resulting force is translated to the power receptacle. Over a period of time, the external stress exerted on the power receptacle from the power cable causes the solder points connecting the power receptacle to the mother board to wear out and break. Once those solder points are broken, the device becomes inoperable unless the mother board is repaired (power receptacle soldered back on) or the entire mother board is replaced.

Servicing a mother board is a tedious and often costly process, and new motherboards are often available at below the cost of fixing or repairing a defective motherboard. The relatively lower costs associated with replacing the laptop's mother board with a new one compared with servicing the old mother board causes many users to discard the old mother board rather than service it. However, even replacing a new mother board can be a hassle and requires some servicing from a technician, whose costs may be significant. Any downtime experienced during the life of the computer system is also not desirable. Thus, the present invention appreciates the benefits of providing a more robust power receptacle connection that would effectively last throughout the lifetime of the computer or other plug-in electrical device.

### SUMMARY OF THE INVENTION

Disclosed is a method and system for improving the connection for the receptacle used to receive external electrical power and transfer power to the mother board in an electrical device, such as a laptop computer. A power receptacle system is provided with a flexible and robust connection to the mother board. The connection is capable of absorbing the constant plugging and unplugging of an adapter head of an external power cable into the receptacle as well as other lateral external forces transferred by an external power cable.

The power receptacle system comprises the following: (1) a first female power receptacle attached and/or fastened to the laptop case; (2) a first male connector within the laptop which is connected to the first female power receptacle by (3) a flexible conducting wire; and (4) a second female receptacle directly connected to the mother board and which is coupled to the first male connector. The external power supply is connected to the first female receptacle via an adapter head (i.e., a second male connector) of the power cable. Inside the casing of the computer, the first female receptacle is connected to a male receptacle by flexible conductive wire. The male receptacle fits into the second female power receptacle which resides on the mother board.

Since the external power supply cable is indirectly attached to the mother board via the flexible wires, the solder joints of the power receptacle on the mother board do not receive external stress, due to the flexible connection of an intermediary conductive wire. The conductive wire dissipates any stress on the first female receptacle, and thus, no measurable stress is passed to the connection to the mother board, regardless of how much stress is applied to the power supply cable. The power receptacle system therefore protects the connection for the second female receptacle utilized for transferring power to the mother board.

The above as well as additional objectives, features, and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 depicts a laptop computer's power receptacle system according to an illustrative embodiment of the invention;

FIG. 2 illustrates a laptop computer, within which features of the invention may be advantageously implemented;

FIG. 3 illustrates a conventional laptop power receptacle system with a direct connection between the mother board of the computer and a female receptacle; and

FIG. 4 depicts a laptop power receptacle system according to an alternate embodiment of the invention.

### DETAILED DESCRIPTION OF AN ILLUSTRATIVE EMBODIMENT

The present invention provides a method and system for improving the connection for the receptacle used to receive external electrical power and transfer power to the mother board in an electrical device, such as a laptop computer. A power receptacle system is provided with a flexible and robust connection to the mother board. The connection is capable of absorbing the constant plugging and unplugging of an adapter head of an external power cable into the receptacle as well as other lateral external forces transferred by an external power cable.

The power receptacle system comprises the following: (1) a first female power receptacle attached and/or fastened to the laptop case; (2) a first male connector within the laptop which is connected to the first female power receptacle by (3) a flexible conducting wire; and (4) a second female receptacle directly connected to the mother board and which is coupled to the first male connector. The external power supply is connected to the first female receptacle via an adapter head (i.e., a second male connector) of the power cable. Inside the casing of the computer, the first female receptacle is connected to a male receptacle by flexible conductive wire. The male receptacle fits into the second female power receptacle which resides on the mother board.

In the following detailed description of exemplary embodiments of the invention, specific exemplary embodiments in which the invention may be practiced are described in sufficient detail to enable those skilled in the art to practice the invention, and it is to be understood that other embodiments may be utilized and that logical, architectural, programmatic, mechanical, electrical and other changes may be made without departing from the spirit or scope of the present invention. The following detailed description is, therefore, not to be taken in a limiting sense, and the scope of the present invention is defined only by the appended claims.

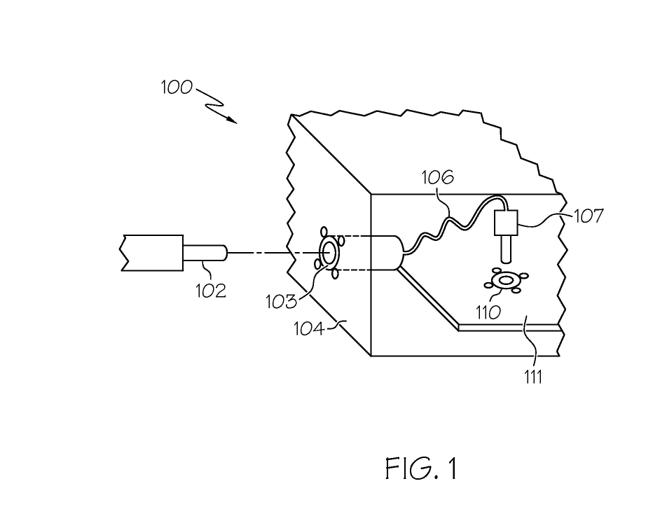

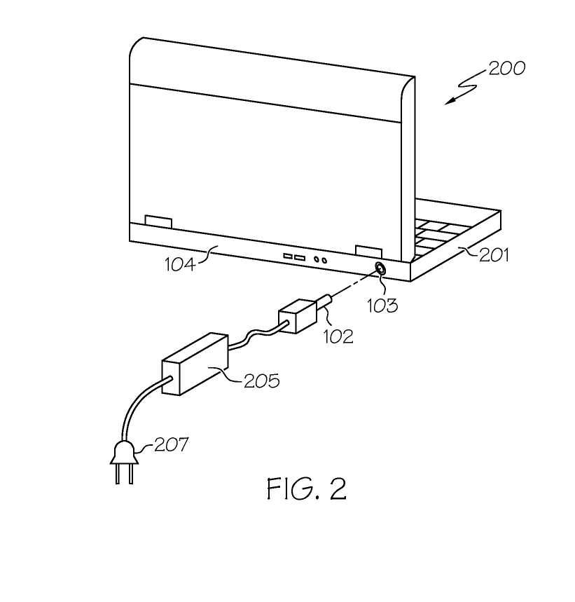

Within the descriptions of the figures, similar elements are provided similar names and reference numerals as those of the previous figure(s). Where a later figure utilizes the element in a different context or with different functionality, the element is provided a different leading numeral representative of the figure number (e.g., 1xx for FIGS. 1 and 2xx for FIG. 2). The specific numerals assigned to the elements are provided solely to aid in the description and not meant to imply any limitations (structural or functional) on the invention.

It is also understood that the use of specific parameter names are for example only and not meant to imply any limitations on the invention. The invention may thus be implemented with different nomenclature/terminology utilized to describe the above parameters, without limitation.

With reference now to the figures, FIG. 2 illustrates an example laptop computer, within which features of the invention may be advantageously implemented. Laptop 200 comprises exterior laptop casing 104 and female receptacle 103. According to the invention, laptop is further coupled to an external power supply (not shown) by power supply cable. Power supply cable comprises a male adapter/connector 102, AC-DC adapter 205, and AC power connector/plug 207.

Laptop 200 is supplied with power when the following actions have taken place: (1) male adapter/connector 102 is connected to (i.e., plugged/inserted into) female connector 103; and (2) AC power connector/plug 207 is connected to an AC power supply. Within laptop 200, female receptacle 103 is soldered to the motherboard, such that the open/insertion point of female receptacle 103 is located along the plane of laptop casing. Female receptacle 103 is utilized to transfer external power to the mother board residing inside of the laptop casing.

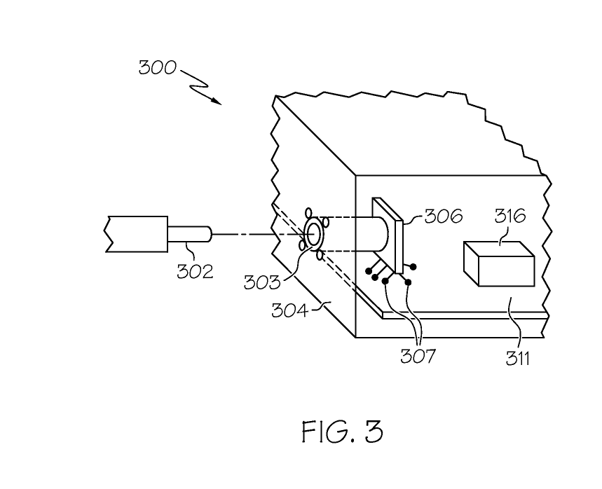

FIG. 3 illustrates a prior art laptop power receptacle system with a direct connection between the mother board of the laptop computer and a female receptacle. As shown, laptop 300 comprises power supply connector (male adapter) 302 which connects to female receptacle 303. Female receptacle 303 is soldered to the motherboard 311. Laptop 300 also comprises solder block 306 which is directly connected to female receptacle 303 within the laptop's interior. Solder block 306 is also directly connected to mother board 311 by solder points 307. Laptop 300 also comprises power detection/converter circuitry 316.

In the configuration presented by laptop 300, the connection allowing the transfer of power to mother board 311 is completed when power supply connector 302 is connected to female receptacle 303. The direct and inflexible (solder) connection between female receptacle 303 and mother board 311 causes external force and/or stress to be transferred to solder points 307, which leads to the weakening (and eventual breakage) of the connection of female receptacle 303 to mother board 311. These forces may originate from the constant plugging and unplugging of power supply connector 302 into female receptacle 303. Ultimately, the constant transfer of force to solder points 307 may cause female receptacle 303 to become separated from mother board 311. This separation from mother board 311 results in a faulty connection which prevents normal laptop operation.

FIG. 1 depicts a laptop power receptacle system designed according to one embodiment of the invention. Laptop 100 comprises first female power receptacle 103 (which is) fastened to laptop casing 104, flexible conducting wire (FCW) 106, and male connector 107. In addition, laptop 100 comprises second female power receptacle 110, which resides on mother board 111.

Within the interior of the laptop computer, first female power receptacle 103 is connected by flexible conductive wire 106 to male connector 107. The flexible nature of flexible conductive wire 106 allows FCW 106 to absorb any force or vibration flexible conductive wire 106 may experience within the laptop computer. Consequently, flexible conductive wire 106 further prevents the transfer of any internal stresses or vibrations to second female power receptacle 110. Finally, male connector 107 is connected to second female power receptacle 110 completing a robust connection for the transfer of power to motherboard 111 of laptop computer 100.

When configured in this manner, laptop 100 is provided a power connection system which allows an external supply of power to be transferred internally to laptop 100 without incurring the level of stress and strain on the mother board connection points to the first female receptacle 103. As shown, the laptop may receive power supply connector (male adapter) 102 at first female power receptacle 103, without the accompanying stresses and strains from the male adapter 102 or the power cable affecting the connection to the motherboard.

The illustrative configuration of laptop 100 is particularly designed to eliminate the stress to the solder joints, which now connect second female power receptacle 110 to mother board 111 of laptop computer 100. With this configuration, external power supply connector 102 connects to first female power receptacle 103, which forwards power to second female power receptacle and ultimately motherboard 111 via flexible wire 106 and male connector 107. First female power receptacle 103 is fastened to laptop casing 104 such that any external jarring is absorbed by (hard) laptop casing 104 and dissipated through flexible conductive wire 106.

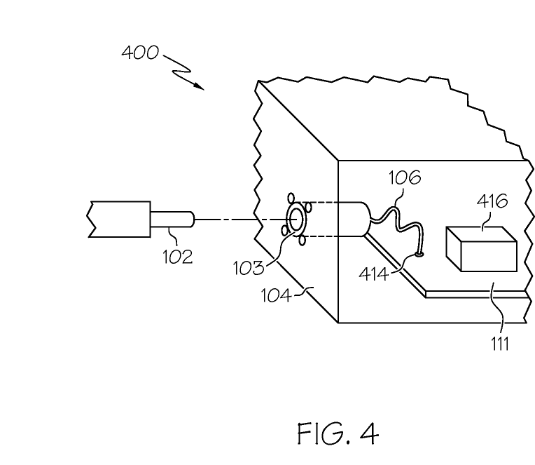

FIG. 4 illustrates a laptop power receptacle system, according to an alternate embodiment of the invention. Laptop 400 comprises female power receptacle 103, laptop casing 104, laptop motherboard 111, and flexible conducting wire 106. Laptop 400 also comprises connection point 414 which connects FCW 106 to motherboard 111. In addition, laptop 400 comprises power detection/converter circuitry 416.

In the illustrative configuration, external power supply connector 102 connects to female power receptacle 103 allowing power to be (indirectly) transferred to laptop motherboard 111 via flexible conductive wire 106. Female power receptacle 103 is fastened to laptop casing 104 such that any external jarring would be absorbed by (hard) laptop casing 104. In the interior of the laptop computer, female power receptacle 103 is connected by flexible conductive wire 106 to motherboard 111, completing a robust connection for the transfer of power to motherboard 111 of laptop computer 400. The flexible nature of flexible conductive wire 106 allows flexible conductive wire 106 to absorb any force or vibration flexible conductive wire 106 may experience within the laptop computer. Consequently, flexible conductive wire 106 further prevents the transfer of any external stresses or vibrations that may cause damage to connection point 414 or other connections within laptop 400.

Although the invention has been illustrated and described with reference to the power receptacles and connections of a laptop computer, the invention may apply to any portable electronic device that may utilize an external power supply, such as, but not limited to cell phones and personal digital assistants (PDAs). The invention also applies to other computers and, in particular, to desktop computers which may be (frequently) transferred from one location to another location.

By implementing the laptop power receptacle system, laptop manufacturers are able to reduce customer down time resulting from issues associated with a faulty power connection in laptop computers. In addition, customers are able to eliminate or minimize the costs associated with the purchasing a new laptop mother board as a result of faulty receptacle connections on the laptop mother board.

While the invention has been particularly shown and described with reference to a preferred embodiment, it will be understood by those skilled in the art that various changes in form and detail may be made therein without departing from the spirit and scope of the invention.

What is claimed is:

1. An electronic device comprising:
a motherboard, which provides a base platform for connection of electrical components that required electrical power for operation;
a power receptacle that receives input of electrical power from an external power supply; and
a flexible conductive wire connecting the power receptacle with the motherboard, wherein internal and external forces on the power receptacle are absorbed and dissipated by the flexible conductive wire without being transferred to a connection point at which the flexible conductive wire connects with the motherboard.

2. The electronic device of claim 1, wherein the power receptacle is a first female power receptacle designed to receive a first male power receptacle of an external power cable.

3. The electronic device of claim 2, further comprising:
a second female power receptacle affixed to the mother board; and
wherein said conductive wire is affixed at one end to the first female power receptacle and at the other end to a second male power receptacle, which is electrically coupled inside of the second female receptacle.

4. The electrical device of claim 1, wherein the device is a computer system and the electrical components include computer system components.

5. The electrical device of claim 1, wherein the device is a portable electrical device that requires recharging of an internal battery via the female power receptacle.

6. The electrical device of claim 1, further comprising:
an internal rechargeable battery; and
means for recharging the internal rechargeable battery using power input received at the female power receptacle.

7. The electrical device of claim 1, wherein said motherboard further comprises a power control circuitry that controls allocation of power received from the power input to the various ones of the electrical components.

8. A laptop computer comprising:
a motherboard, which provides a base platform for connection of electrical components that required electrical power for operation;
a power receptacle that receives input of electrical power from an external power supply; and
a flexible conductive wire connecting the power receptacle with the motherboard, wherein internal and external forces on the power receptacle are absorbed and dissipated by the flexible conductive wire without being transferred to a connection point at which the flexible conductive wire connects with the motherboard.

9. The laptop computer of claim 8, wherein the power receptacle is a first female power receptacle designed to receive a first male power receptacle of an external power cable.

10. The laptop computer of claim 9, further comprising:
a second female power receptacle affixed to the mother board; and
wherein said conductive wire is affixed at one end to the first female power receptacle and at the other end to a second male power receptacle, which is electrically coupled inside of the second female receptacle.

11. The laptop computer of claim 8, further comprising:
an internal rechargeable battery; and
means for recharging the internal rechargeable battery using power input received at the female power receptacle.

12. The laptop computer of claim 1, wherein said motherboard further comprises a power control circuitry that controls allocation of power received from the power input to the various ones of the electrical components.

13. A method for manufacturing an electronic device having a motherboard on which electrical components that require electrical power input are disposed, the method comprising:
coupling a first end of a flexible conductive wire to the power input connection point of the motherboard;
connecting a second end of the flexible conductive wire to a female power receptacle that includes a receiving end positioned to receive input power via an external male receptacle of an external power cable;
wherein internal and external forces on the power receptacle are absorbed and dissipated by the flexible conductive wire without being transferred to the power input connection point at which the flexible conductive wire connects with the motherboard.

14. The method of claim 13, wherein said power input connection point includes a second female power receptacle connected to the motherboard, and said coupling further comprises:
connecting an internal male power receptacle to the first end of the flexible conductive wire; and
inserting the male power receptacle to the second female receptacle.

15. The method of claim 13, further comprising:
providing power control logic on the motherboard to control allocation of received input power to the various ones of electrical components disposed on the mother board.
